(19) United States
(12) Patent Application Publication
(10) Pub. No.: US 2017/0345673 A1
(43) Pub. Date: Nov. 30, 2017

(54) METHOD OF SELECTIVE SILICON OXIDE ETCHING

(71) Applicant: Tokyo Electron Limited, Tokyo (JP)

(72) Inventors: Alok Ranjan, Tomiya-shi (JP); Akira Koshiishi, Kofu-City (JP); Sonam D. Sherpa, Albany, NY (US); Vinayak Rastogi, Albany, NY (US)

(21) Appl. No.: 15/604,441

(22) Filed: May 24, 2017

Related U.S. Application Data
(60) Provisional application No. 62/342,990, filed on May 29, 2016.

(51) Int. Cl. H01L 21/311; H01L 21/324

(52) U.S. Cl. CPC H01L 21/31116; H01L 21/324

(57) ABSTRACT

Embodiments of the invention provide a substrate processing method for selective SiO₂ etching relative to other layers used in semiconductor manufacturing. The method includes providing a substrate containing a first layer containing SiO₂ and a second layer that is different from the first layer, forming a plasma-excited process gas containing 1) NF₃ and NH₃, 2) NF₃, N₂ and H₂, or 3) NF₃, NH₃, N₂ and H₂, and exposing the substrate to the plasma-excited process gas to selectively etch the first layer relative to the second layer. According to one embodiment, the second layer includes SiN or elemental Si.

### CROSS-REFERENCE TO RELATED APPLICATIONS

This application is related to and claims priority to U.S. Provisional Patent Application Ser. No. 62/342,990 filed on May 29, 2016, the entire contents of which are herein incorporated by reference.

### FIELD OF INVENTION

The present invention relates to the field of semiconductor manufacturing and semiconductor devices, and more particularly, to a method of selective silicon oxide etching relative to other type of layers used in semiconductor manufacturing.

### BACKGROUND OF THE INVENTION

Next generation semiconductor technology development poses a huge challenge as dry etch removal of silicon oxide selective to silicon, silicon nitride and other underlying layers is needed. Current fluorocarbon chemistry used for silicon oxide etch becomes extremely difficult to control at narrow mask openings and high aspect ratios due to polymer deposition flux. The process margin diminishes with each subsequent technology node. Hence the need for a new chemistry free from polymer deposition and in turn bypassing the additional challenges of existing processes.

### SUMMARY OF THE INVENTION

Embodiments of the invention describe substrate processing methods using non-polymerizing chemistry to selectively etch SiO₂ relative to other layers used in semiconductor manufacturing. According to one embodiment, the method includes providing a substrate containing a first layer containing SiO₂ and a second layer that is different from the first layer, forming a plasma-excited process gas containing 1) NF₃ and NH₃, 2) NF₃, N₂ and H₂, or 3) NF₃, NH₃, N₂ and H₂, and exposing the substrate to the plasma-excited process gas to selectively etch the first layer relative to the second layer. According to one embodiment, the second layer includes SiN or elemental Si.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1A and 1B schematically show through cross-sectional views a method of processing a substrate according to an embodiment of the invention;

FIGS. 2A-2C schematically show through cross-sectional views a method of processing a substrate according to another embodiment of the invention;

FIGS. 3A and 3B schematically show through cross-sectional views a method of processing a substrate according to still another embodiment of the invention;

FIGS. 4A and 4B schematically show through cross-sectional views a method of processing a substrate according to an embodiment of the invention;

FIGS. 5A and 5B schematically show through cross-sectional views a method of processing a substrate according to another embodiment of the invention;

FIGS. 6A and 6B schematically show through cross-sectional views a method of processing a substrate according to still another embodiment of the invention;

FIGS. 7A-7C schematically show through cross-sectional views a method of processing a substrate according to an embodiment of the invention;

FIGS. 8A-8C schematically show through cross-sectional views a method of processing a substrate according to an embodiment of the invention;

FIGS. 9A-9C show experimental results for selective SiO₂ etching relative to SiN according to embodiments of the invention;

FIGS. 10A-10C schematically show through cross-sectional views a method of processing a substrate according to an embodiment of the invention;

FIG. 11 shows experimental results for selective SiO₂ etching relative to SiN according to an embodiment of the invention;

FIG. 12 schematically shows an atomic layer deposition (ALD) system according to an embodiment of the invention; and

FIG. 13 schematically shows a capacitively coupled plasma (CCP) system according to an embodiment of the invention.

### DETAILED DESCRIPTION OF SEVERAL EMBODIMENTS

Embodiments of the invention describe substrate processing methods using a non-polymerizing chemistry to selectively etch SiO₂ relative to SiN, Si, and other Si-containing layers. According to one embodiment of the invention, the method includes providing a substrate containing a first layer containing SiO₂ and a second layer that is different from the first layer, plasma-exciting a non-polymerizing process gas containing a) NF₃ and NH₃, 2) NF₃, N₂ and H₂, or 3) NF₃, NH₃, N₂ and H₂, and exposing the substrate to the plasma-excited process gas to selectively etch the first layer relative to the second layer. In one example, the second layer includes SiN or elemental Si. Elemental Si can include polycrystalline Si and amorphous Si. Several examples are described herein that can benefit from using the plasma-excited non-polymerizing process gas for selective etching.

The inventors have discovered that the non-polymerizing process gas provides excellent selective dry etch removal of SiO₂ relative to layers that include SiN and elemental Si. This is in contrast to currently existing fluorocarbon chemistry used for SiO₂ dry etch which is extremely difficult to control at narrow feature openings and high aspect ratios due to polymer deposition flux from the fluorocarbon chemistry.

As used herein, the notation “SiN” includes layers that contain silicon and nitrogen as the major constituents, where the layers can have a range of Si and N compositions. Si₃N₄ is the most thermodynamically stable of the silicon nitrides and hence the most commercially important of the silicon nitrides. However, embodiments of the invention may be applied to SiN layers having a wide range of Si and N compositions. Furthermore, the notation “SiO₂” is meant to include layers that contain silicon and oxygen as the major constituents, where the layers can have a range of Si and O compositions. SiO₂ is the most thermodynamically stable of the silicon oxides and hence the most commercially important of the silicon oxides.

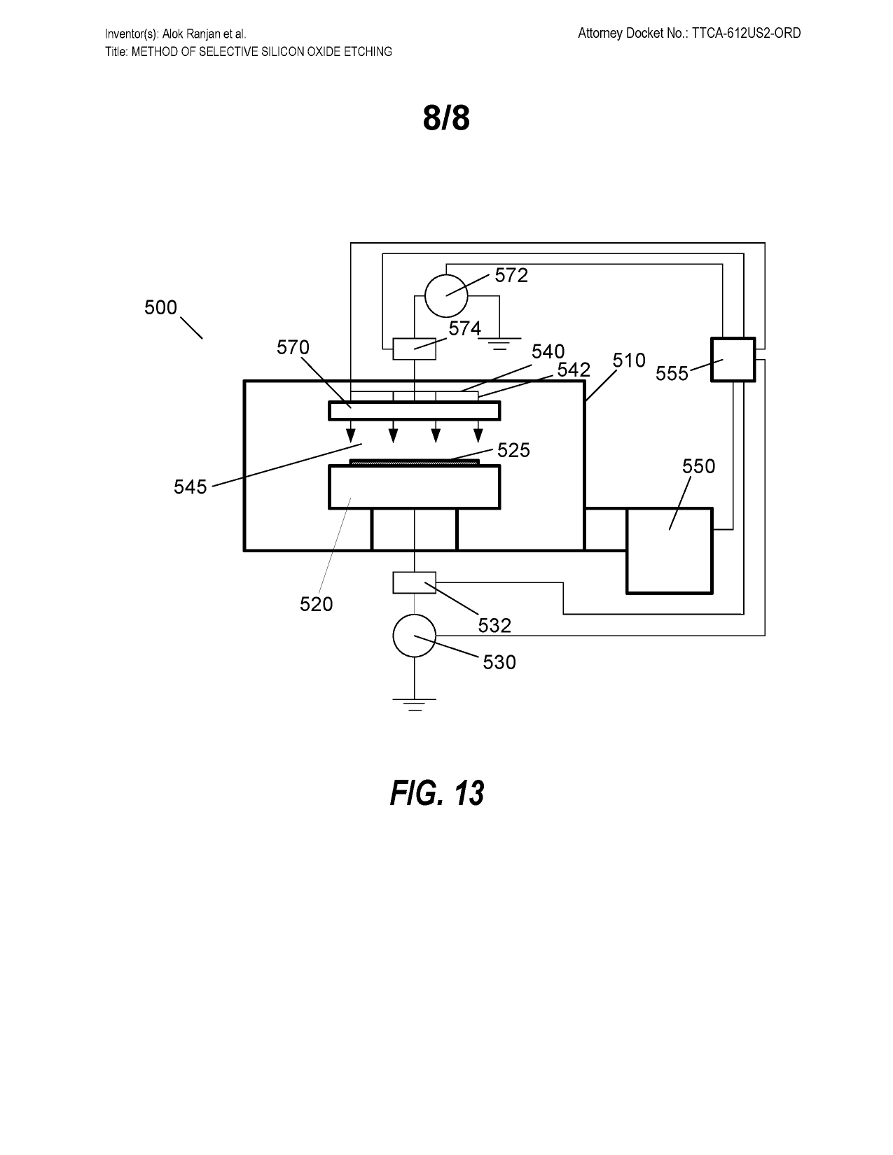

The non-polymerizing process gas may be plasma excited using a variety of different plasma sources. According to one embodiment, the plasma source can include a capacitively coupled plasma (CCP) source that contains an upper plate electrode, and a lower plate electrode supporting the substrate. Radio frequency (RF) power may be provided to the upper plate electrode, the lower plate electrode, or both, using RF generators and impedance networks. A typical frequency for the application of RF power to the upper electrode can range from 10 MHz to 200 MHz and may be 60 MHz. Additionally, a typical frequency for the application of RF power to the lower electrode can range from 0.1 MHz to 100 MHz and may be 13.56 MHz. A CCP system that may be used to perform the spacer etch process is schematically shown in FIG. 13. Exemplary processing parameters include gas pressure between about 5 mTorr and about 600 mTorr or between about 10 mTorr and about 600 mTorr, and substrate temperature between about −10° C. and about 250° C. or between about 0° C. and about 200° C.

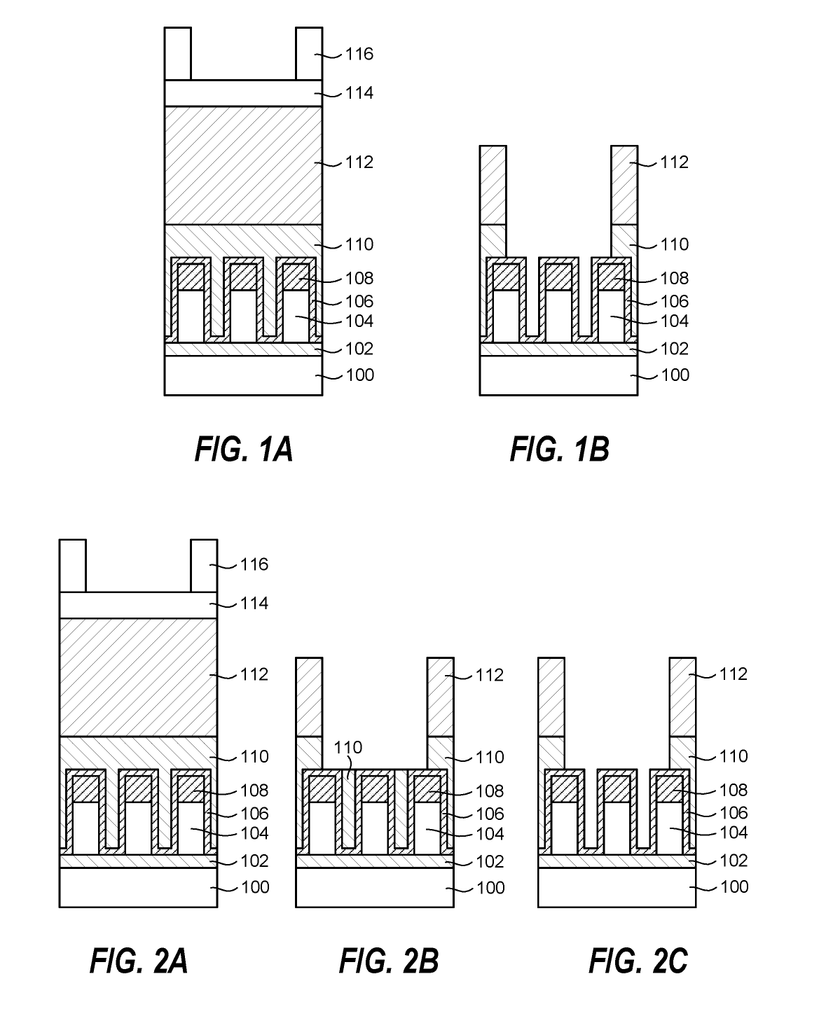

FIGS. 1A and 1B schematically show through cross-sectional views a method of processing a substrate according to an embodiment of the invention. FIG. 1A shows a substrate 100, a SiO₂ layer 102, raised features 104 (e.g., containing amorphous Si), a SiN spacer layer 106 conformally formed on a SiN hardmask 108, and SiO₂ layer 110 filling openings between the raised features 104. FIG. 1A further shows an organic dielectric layer (ODL) 112, a Si-containing anti-reflective coating (SiARC) 114, and a patterned photoresist layer 116.

According to an embodiment of the invention, one or more dry etch processes are performed on the structure shown in FIG. 1A to form the structure shown in FIG. 1B. The one or more dry etch processes provide full oxide removal down to the SiN spacer layer 106 between the raised features 104. The full oxide removal process is commonly referred to as a self-aligned contact (SAC) etch. The one or more dry etch processes can include the plasma-excited non-polymerizing process gas that anisotropically and selectively etches the SiO₂ layer 110 and stops on the SiN spacer layer 106.

FIGS. 2A-2C schematically show through cross-sectional views a method of processing a substrate according to another embodiment of the invention. FIG. 1A is described above and has been reproduced as FIG. 2A. According to an embodiment of the invention, one or more anisotropic dry etch process are performed on the structure shown in FIG. 2A to form the structure shown in FIG. 2B. The one or more dry etch processes can use fluorocarbon chemistry to provide partial oxide removal down to approximately the top of the SiN spacer layer 106 on the SiN hardmask 108. Thereafter, as depicted in FIG. 2C, full oxide removal may be performed down to the SiN spacer layer 106 between the raised features 104 using the plasma-excited non-polymerizing process gas.

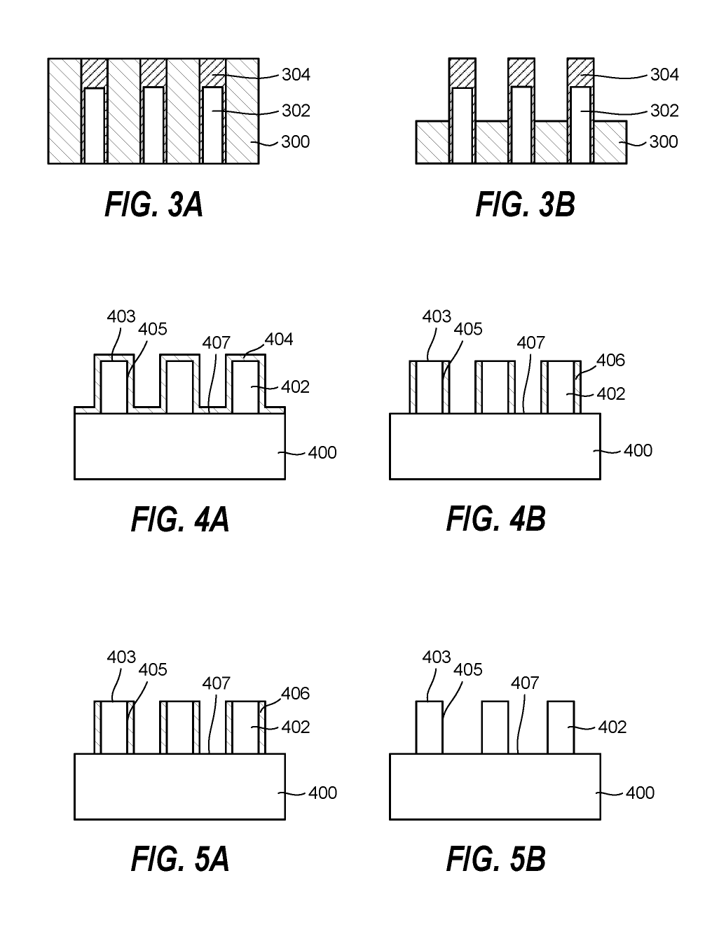

FIGS. 3A and 3B schematically show through cross-sectional views a method of processing a substrate according to still another embodiment of the invention. FIG. 3A shows a structure containing a SiO₂ layer 300, raised features 302, and a SiN hardmask 304 formed on the raised features 302. The raised features 302 may be referred to as fins and can, in one example, contain amorphous silicon. According to an embodiments of the invention, the structure in FIG. 3A may be processed using the plasma-excited non-polymerizing process gas to anisotropically and selectively etch the SiO₂ layer 300 to uncover at least a portion of the SiN hardmask 304 formed on the raised features 302. The processed substrate is shown FIG. 3B. In one example, the processing shown in FIGS. 3A and 3B may generally be referred to as an oxide pullback to reveal fins.

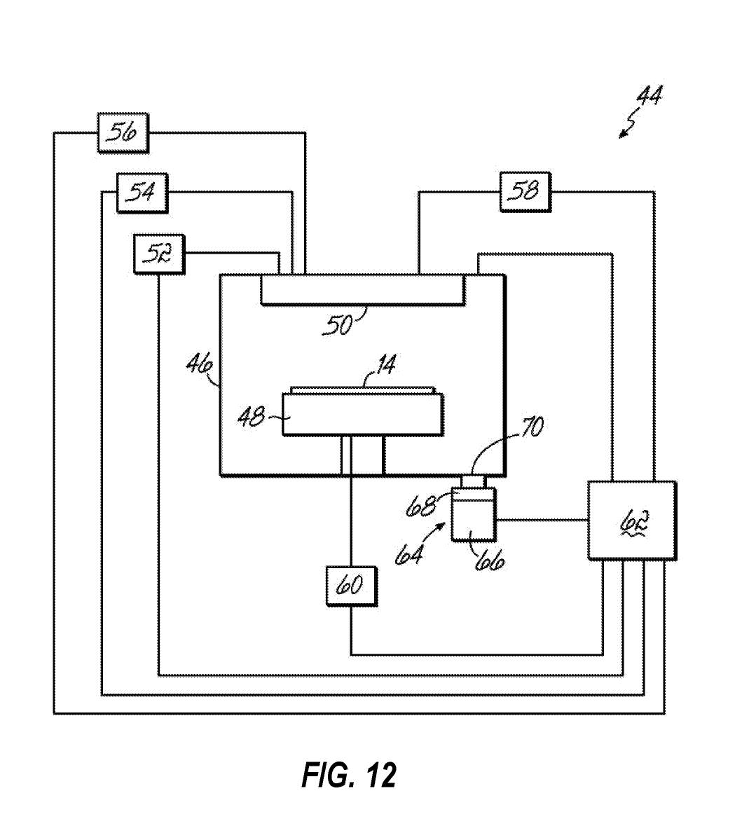

FIGS. 4A and 4B schematically show through cross-sectional views a method of processing a substrate according to an embodiment of the invention. FIG. 4A shows a substrate 400, raised features 402 on the substrate 400, and a conformal SiO₂ spacer layer 404 deposited on the exposed surfaces of the raised features 402 and on surface 407 of the substrate 400 between the raised features 402. The exposed surfaces of the raised features 402 include vertical portions 405 and horizontal portions 403. The substrate 400 and the raised features 402 may, for example, contain SiN or elemental Si. In some microelectronic devices, the raised features 402 are referred to as fins. An ALD system that may be used for depositing the SiO₂ spacer layer 404 is schematically shown in FIG. 12.

According to an embodiment of the invention, an anisotropic spacer etch process using the plasma-excited non-polymerizing process gas may be performed on the structure shown in FIG. 4A to form the structure shown in FIG. 4B. The spacer etch process forms SiO₂ sidewall spacers 406 on the vertical portions 405 of the raised features 402 by removing the SiO₂ spacer layer 104 from the horizontal portions 403 and the surface 407 of the substrate 400 while leaving the SiO₂ spacer layer 404 on the vertical portions 405.

FIGS. 5A and 5B schematically show through cross-sectional views a method of processing a substrate according to another embodiment of the invention. FIG. 4A has been reproduced as FIG. 5A and shows a substrate 400, raised features 402 on the substrate 400, and SiO₂ sidewall spacers 406 on the vertical portions 405 of the raised features 402. The substrate 400 and the raised features 402 may, for example, contain SiN or elemental Si.

According to one embodiment, the SiO₂ sidewall spacers 406 may be removed from the vertical portions 405 of the raised features 402 in a dry etching process. The resulting structure is shown in FIG. 5B. According to embodiments of the invention, the removal of the SiO₂ sidewall spacers 406 may be performed using the plasma-excited non-polymerizing process gas, where the etching process is carried out for a longer time period that the etching process shown in FIGS. 4A and 4B. Furthermore, plasma processing conditions that provide isotropic etching may be chosen.

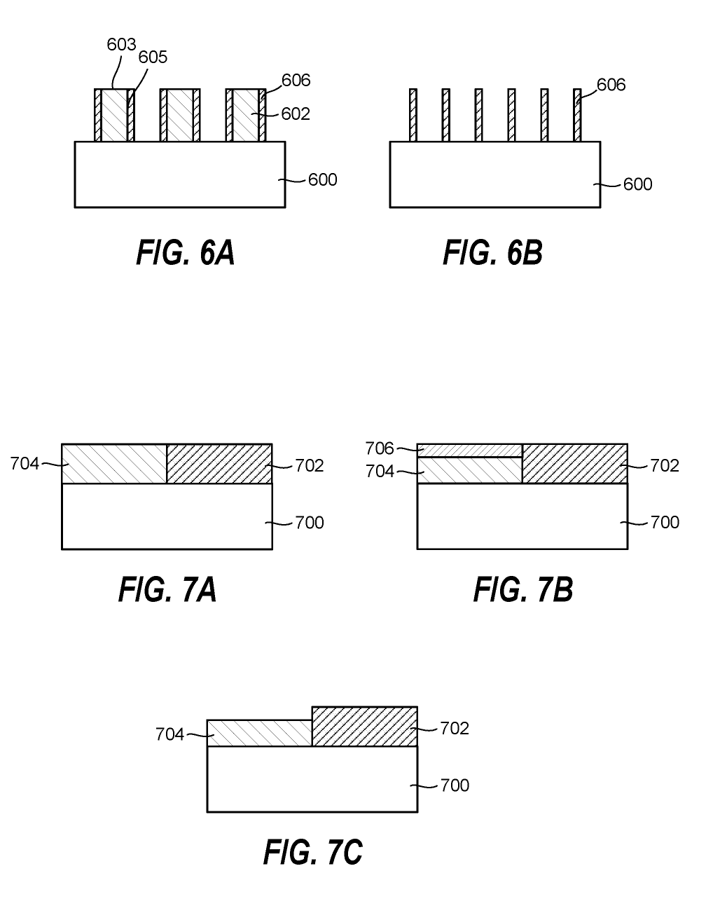

FIGS. 6A and 6B schematically show through cross-sectional views a method of processing a substrate according to still another embodiment of the invention. FIG. 6A shows a substrate 600, SiO₂ raised features 602 on the substrate 600, and sidewall spacers 606 formed on the vertical portions 605 of the SiO₂ raised features 602. The horizontal portions 603 of the SiO₂ raised features 602 are exposed by a prior etch process. The substrate 600 and the sidewall spacers 606 may, for example, contain SiN or elemental Si. In this embodiment, the SiO₂ raised features 602 are sacrificial features and are commonly referred to as mandrels, and the removal of the SiO₂ raised features 602 is commonly referred to as a mandrel pull. The structure shown in FIG. 6A may be formed by creating SiO₂ raised features 602 using conventional deposition, lithography, and etching processes. Thereafter, the sidewall spacers 606 may be formed using a conformal deposition process, followed by an anisotropic etch process.

According to one embodiment, the SiO₂ raised features 602 are removed from the substrate 600 in an anisotropic dry etching process using the plasma-excited non-polymerizing process gas. The resulting structure with free-standing sidewall spacers 606 on the substrate 600 is shown in FIG. 6B.

FIGS. 7A-7C schematically show through cross-sectional views a method of processing a substrate according to an embodiment of the invention. FIG. 7A shows a substrate 700, a first layer 704 containing SiO₂, and a second layer 702 containing SiN or elemental Si. According to one embodiment, the first layer 704 and the second layer 702 are exposed to a plasma-excited non-polymerizing process gas containing N₂, H₂, NH₃, and NF₃, to modify a portion of the first layer 704 and thereby form a modified first layer 706 on the first layer 704 as shown in FIG. 7B. The modified first layer 706 can contain (NH₄)₂SiF₆ reaction products formed by the reactions:

SiO₂+4F+4NH₃→SiF₄+2H₂O+4NF₃

SiF₄+2HF+2NH₃→(NH₄)₂SiF₆

The modified first layer 706 may be removed from the first layer 704 using substrate heating, ion bombardment, or both substrate heating and ion bombardment. The resulting structure is shown in FIG. 7C where the first layer 704 has been thinned. The substrate heating provides isotropic removal of the modified first layer 706, in contrast to the ion bombardment which can be anisotropic. Removal of the modified first layer 706 may be described as:

(NH₄)₂SiF₆→SiF₄+2HF+2NH₃

The exposure and removal steps may be repeated at least once until the first layer 704 has reached a desired thickness or has been completely removed from the substrate 700. According to one embodiment, the substrate heating, ion bombardment, or both substrate heating and ion bombardment, may be performed during the exposure to the plasma-excited non-polymerizing process gas, resulting in continuous formation and removal of the modified first layer 706.

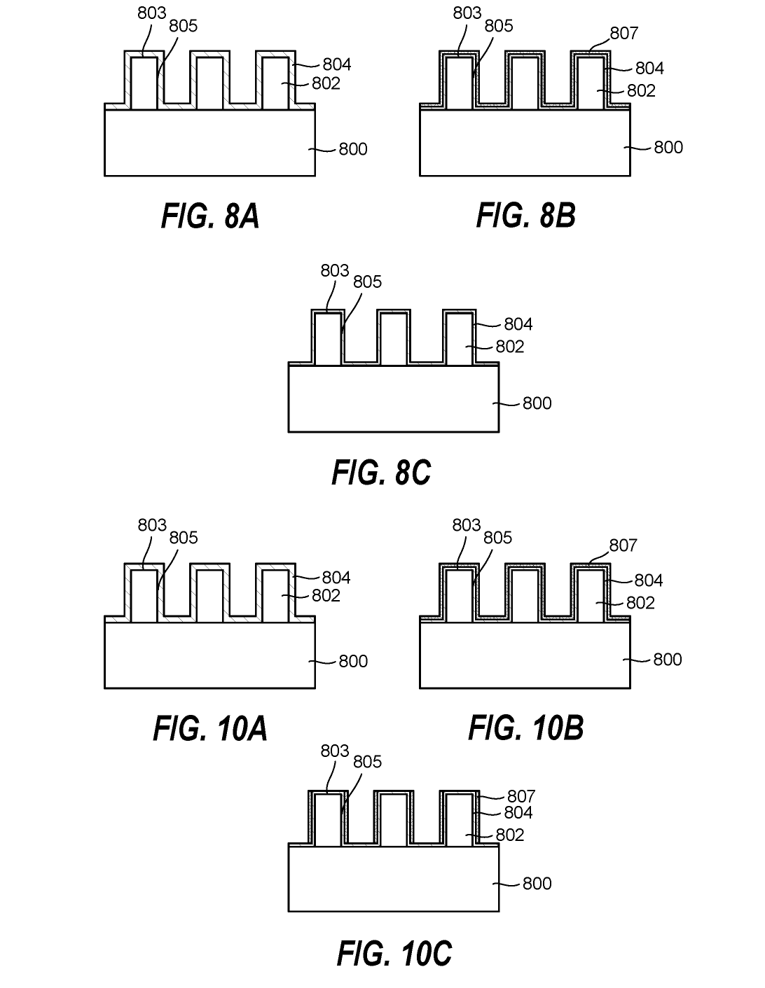

FIGS. 8A-8C schematically show through cross-sectional views a method of processing a substrate according to an embodiment of the invention. FIG. 8A shows a substrate 800, raised features 802 on the substrate 800, and a SiO₂ spacer layer 804 conformally formed on the exposed surfaces of the raised features 802 and the substrate 800. The exposed surfaces of the raised features 802 include vertical portions 805 and horizontal portions 803. The substrate 800 and the raised features 802 may, for example, contain SiN or elemental Si.

According to an embodiment of the invention, structure in FIG. 8A is exposed to the plasma-excited non-polymerizing process gas to form a modified spacer layer 807 on the SiO₂ spacer layer 804. The processing conditions may be selected such that heating, ion bombardment, or both heating and ion bombardment, do not remove the modified spacer layer 807 during the plasma exposure. The resulting structure is shown in FIG. 8B. Thereafter, the modified spacer layer 807 may be isotropically removed using substrate heating, for example in a heat-treating chamber. The resulting structure is shown in FIG. 8C where the SiO₂ spacer layer 804 from FIG. 8A has been thinned.

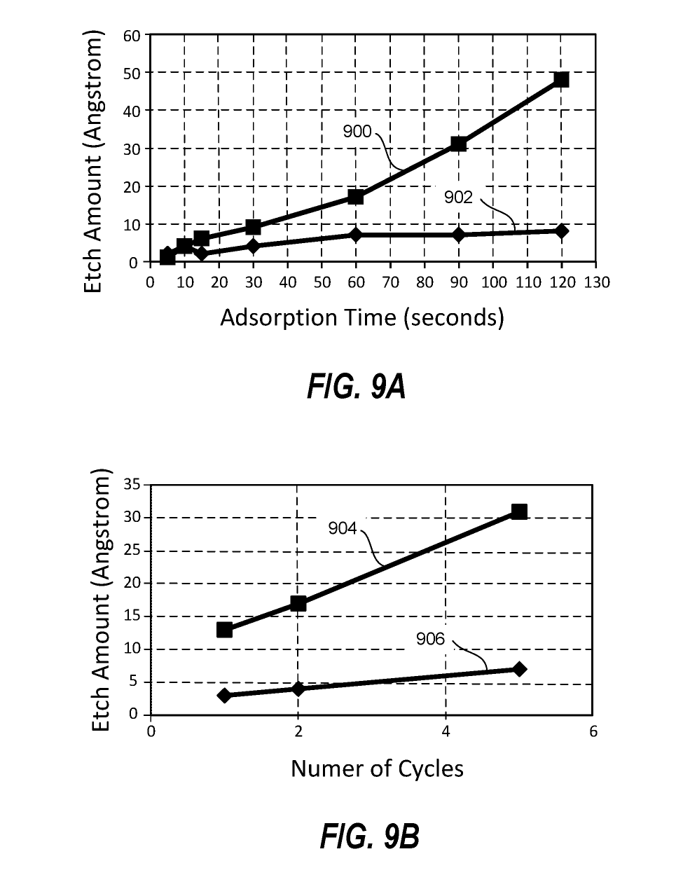

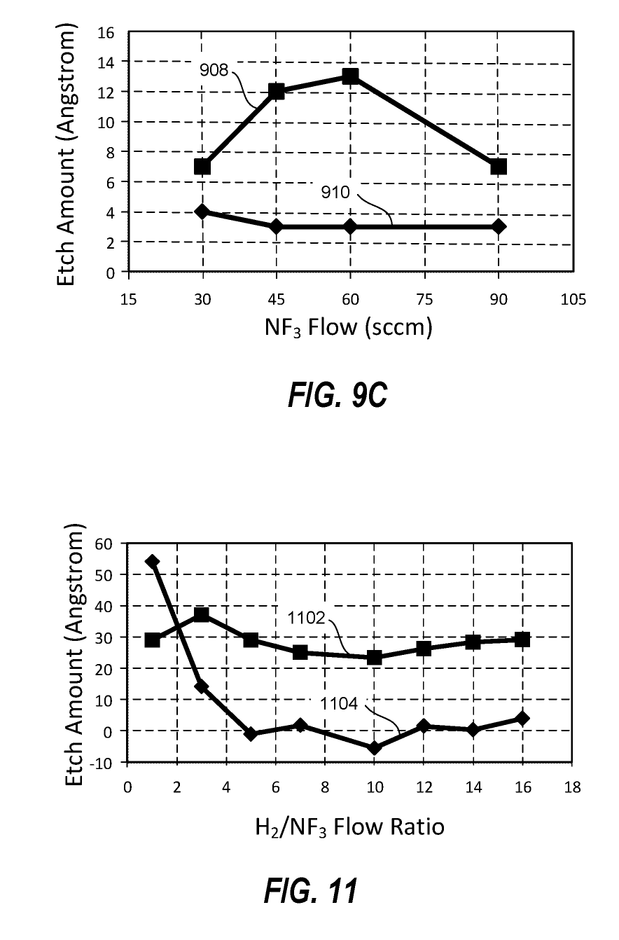

FIGS. 9A-9C show experimental results for selective SiO₂ etching relative to SiN according to embodiments of the invention. The blanket film samples were exposed to plasma-excited process gas containing NF₃, N₂ and H₂, in a CCP plasma processing chamber to form a modified layer, and thereafter the modified layer was isotropically removed using substrate heating in a heat-treating chamber.

In FIG. 9A, the plasma processing included a remote source CCP that created a high radical to ion flux ratio and was powered with 1500 W at 400 kHz with power being equally distributed to the top and bottom electrode. The processing conditions included a chamber pressure of 250 mTorr, H₂ gas flow of 180 sccm, N₂ gas flow of 60 sccm, Ar gas flow of 720 sccm, NF₃ gas flow of 60 sccm, substrate holder temperature of 15° C., and plasma exposure times (adsorption time) from 5-120 seconds. The substrate holder was not powered. The heat-treating conditions included a chamber pressure of 1 Torr, N₂ gas flow of 1000 sccm, substrate holder temperature of greater than 100° C., and heat-treating time of 180 seconds. The plasma exposure and subsequent heat-treating were performed 5 times (5 cycles). The SiO₂ etch amount is shown by trace 900 and the SiN etch amount is shown by trace 902. FIG. 9B shows the experimental results for performing the plasma exposure and heat-treating 1-5 times (1-5 cycles). The SiO₂ etch amount is shown by trace 904 and the SiN etch amount is shown by trace 906. In FIG. 9C shows the experimental results for NF₃ gas flows of 30-90 sccm, and plasma exposure times of 90 seconds. The SiO₂ etch amount is shown by trace 908 and the SiN etch amount is shown by trace 910. In summary, FIGS. 9A-9C show that selective SiO₂ etching relative to SiN is maintained for long plasma exposure times, a large number of exposure cycles, and moderate NF₃ gas flows.

FIGS. 10A-10C schematically show through cross-sectional views a method of processing a substrate according to an embodiment of the invention. FIG. 8A is reproduced as FIG. 10A and has been described above.

According to an embodiment of the invention, structure in FIG. 10A is exposed to the plasma-excited non-polymerizing process gas to form a modified spacer layer 807 on the SiO₂ spacer layer 804. The processing conditions may be selected such that heating, ion bombardment, or both heating and ion bombardment, do not remove the modified spacer layer 807 during the plasma exposure. The resulting structure is shown in FIG. 10B. Thereafter, the modified spacer layer 807 may be anisotropically removed from the horizontal portions 803 using ion bombardment, while leaving the modified spacer layer 807 on the vertical portions 805. The resulting structure is shown in FIG. 10C. The ion bombardment may be performed using a plasma exposure.

FIG. 11 shows experimental results for selective SiO₂ etching relative to SiN according to an embodiment of the invention. The blanket film samples were exposed to plasma-excited process gas containing N₂, H₂, NF₃, and NH₃ in a plasma processing chamber. The H₂/NF₃ flow ratio was varied between 1 and 16. The SiO₂ etch amount is shown by trace 1102 and the SiN etch amount is shown by trace 1104. The results demonstrate selective SiO₂ etching via formation of a modified layer and ion bombardment.

Referring now to FIG. 12, a technique of conformally depositing a SiO₂ spacer layer (e.g., layer 404 in FIG. 4A) may include a monolayer deposition (“MLD”) method. The MLD method may include, for example, an ALD method, which is based on the principle of the formation of a saturated monolayer of reactive precursor molecules by chemisorption. A typical MLD process for forming an AB film, for example, consists of injecting a first precursor or reactant A (“R_{A}”) for a period of time in which a saturated monolayer of A is formed on the substrate. Then, R_{A} is purged from the chamber using an inert gas, G. A second precursor or reactant B (“R_{B}”) is then injected into the chamber, also for a period of time, to combine B with A and form the layer AB on the substrate. R_{B} is then purged from the chamber. This process of introducing precursors or reactants, purging the reactor, introducing another or the same precursors or reactants, and purging the reactor may be repeated a number of times to achieve an AB film of a desired thickness. The thickness of an AB film deposited in each ALD cycle may range from about 0.5 angstrom to about 2.5 angstrom.

In some embodiments, the MLD process when forming an AB film may include injecting a precursor containing ABC, which is adsorbed on the substrate during the first step, and then removing C during the second step.

In accordance with one embodiment of the invention, a conformal SiO₂ layer may be deposited by an ALD deposition process in an ALD system, one example of which is shown as ALD system 44 in FIG. 12, which includes a process chamber 46 having a substrate holder 48 configured to support the substrate 14 thereon. The process chamber 46 further contains an upper assembly 50 (for example, a shower head) coupled to a first gas supply system 52 (which may include a silicon-containing gas), a second gas supply system 54 (which may include an oxygen-containing gas), a purge gas supply system 56, and one or more auxiliary gas supply systems 58 (which may include a dilution gas, or other as necessary for depositing the desired spacer layer layer), and a substrate temperature control system 60.

Alternatively, or in addition, a controller 62 may be coupled to one or more additional controllers/computers (not shown), which may obtain setup and/or configuration information from the additional controllers/computers. The controller 62 may be used to configure any number of the processing elements 52, 54, 56, 58, 60, and may collect, provide, process, store, and/or display data from the same. The controller 62 may comprise a number of applications for controlling one or more of the processing elements 52, 54, 56, 58, 60, and may, if desired, include a graphical user interface (“GUI,” not shown) that may provide an easy to use interface for a user to monitor and/or control one or more of the processing elements 52, 54, 56, 58, 60.

The process chamber 46 is further coupled to a pressure control system 64, including a vacuum pumping system 66 and a valve 68, through a duct 70, wherein the pressure control system 64 is configured to controllably evacuate the process chamber 10 to a pressure suitable for forming the conformal SiO₂ layer and suitable for use of the first and second process layers. The vacuum pumping system 66 may include a turbo-molecular vacuum pump (“TMP”) or a cryogenic pump that is capable of a pumping speed up to about 5000 liters per second (and greater) and the valve 68 may include a gate valve for throttling the chamber pressure. Moreover, a device (not shown) for monitoring the chamber process may be coupled to the process chamber 46. The pressure control system 64 may, for example, be configured to control the process chamber pressure between about 0.1 Torr and about 100 Torr during an ALD process.

The first and second gas supply systems 52, 54, the purge gas supply system 56, and each of the one or more auxiliary gas supply systems 58 may include one or more pressure control devices, one or more flow control devices, one or more filters, one or more valves, and/or one or more flow sensors. The flow control devices may include pneumatic driven valves, electro-mechanical (solenoidal) valves, and/or high-rate pulsed gas injection valves. According to embodiments of the invention, gases may be sequentially and alternately pulsed into the process chamber 46, where the length of each gas pulse may, for example, be between about 0.1 second and about 100 seconds. Alternately, the length of each gas pulse may be between about 1 second and about 10 seconds. Exemplary gas pulse lengths for silicon- and oxygen-containing gases may be between about 0.3 second and about 3 seconds, for example, about 1 second. Exemplary purge gas pulses may be between about 1 second and about 20 seconds, for example, about 3 seconds. Still referring to FIG. 12, the controller 62 may comprise a microprocessor, memory, and a digital I/O port capable of generating control voltages sufficient to communicate and activate inputs to the ALD system 44, as well as monitor outputs from the ALD system 44. Moreover, the controller 62 may be coupled to and may exchange information with the process chamber 46, the substrate holder 48, the upper assembly 50, the processing elements 52, 54, 56, 58, the substrate temperature control system 60, and the pressure control system 64. For example, a program stored in a memory of the controller 62 may be utilized to activate the inputs to the aforementioned components of the ALD system 44 according to a process recipe in order to perform a deposition process.

The controller 62 may be implemented as a general purpose computer system that performs a portion or all of the microprocessor-based processing steps of the present invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 62 includes at least one computer readable medium or memory, such as the controller memory, for holding instructions programmed according to the teachings of the invention and for containing data structures, tables, records, or other data that may be necessary to implement the present invention. Examples of computer readable media are hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, resides software for controlling the controller 62, for driving a device or devices for implementing the present invention, and/or for enabling the controller 62 to interact with a human user. Such software may include, but is not limited to, device drivers, operating systems, development tools, and applications software. Such computer readable media further includes the computer program product of the present invention for performing all or a portion (if processing is distributed) of the processing performed in implementing the present invention.

The computer code devices may be any interpretable or executable code mechanism, including but not limited to scripts, interpretable programs, dynamic link libraries (“DLLs”), Java classes, and complete executable programs. Moreover, parts of the processing of the present invention may be distributed for better performance, reliability, and/or cost.

The term “computer readable medium” as used herein refers to any medium that participates in providing instructions to the processor of the controller 62 for execution. Thus, computer readable medium may take many forms, including but not limited to, non-volatile media, volatile media, and transmission media. Non-volatile media includes, for example, optical, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to the processor of the controller 62 for execution. For example, the instructions may initially be carried on a magnetic disk of a remote computer. The remote computer can load the instructions for implementing all or a portion of the present invention remotely into a dynamic memory and send the instructions over a network to the controller 62.

The controller 62 may be locally located relative to the ALD system 44, or it may be remotely located relative to the ALD system 44. For example, the controller 62 may exchange data with the ALD system 44 using at least one of a direct connection, an intranet, the Internet and a wireless connection. The controller 62 may be coupled to an intranet at, for example, a customer site (i.e., a device maker, etc.), or it may be coupled to an intranet at, for example, a vendor site (i.e., an equipment manufacturer). Additionally, for example, the controller 62 may be coupled to the Internet. Furthermore, another computer (i.e., controller, server, etc.) may access, for example, the controller 62 to exchange data via at least one of a direct connection, an intranet, and the Internet. As also would be appreciated by those skilled in the art, the controller 62 may exchange data with the ALD system 44 via a wireless connection.

Deposition of the conformal SiO₂ layer may proceed by sequential and alternating pulse sequences to deposit the different components (here, for example, silicon and oxygen) of the conformal SiO₂ layer. Since ALD processes typically deposit less than a monolayer of the component per gas pulse, it is possible to form a homogenous layer using separate deposition sequences of the different components of the film. Each gas pulse may include a respective purge or evacuation step to remove unreacted gas or byproducts from the process chamber 46. According to other embodiments of the present invention, one or more of the purge or evacuation steps may be omitted.

Therefore, and as one exemplary embodiment, the substrate 14 with the processed raised features 102 is disposed in the process chamber 46 of the ALD system 44 and sequentially exposed to a gas pulse containing silicon and a gas pulse of an oxygen-containing gas, the latter of which may include H₂O, plasma-exited oxygen (such as for use in PEALD systems), or a combination thereof, and optionally an inert gas, such as argon (Ar).

The silicon may react on the surface of the raised feature 102 to form a chemisorbed layer that is less than a monolayer thick. The oxygen from the gas pulse of the oxygen-containing gas may then react with the chemisorbed surface layer. By repeating this sequential gas exposure, i.e., by alternating the two exposures a plurality of times, it is possible to achieve layer-by-layer growth of about 1 angstrom (10⁻¹⁰ meter) per cycle until a desired thickness is achieved.

Exemplary plasma processing system 500 depicted in FIG. 13 including a chamber 510, a substrate holder 520, upon which a substrate 525 to be processed is affixed, a gas injection system 540, and a vacuum pumping system 550. Chamber 510 is configured to facilitate the generation of plasma in a processing region 545 adjacent a surface of substrate 525, wherein plasma is formed via collisions between heated electrons and an ionizable gas. An ionizable gas or mixture of gases is introduced via the gas injection system 540 and the process pressure is adjusted. For example, a gate valve (not shown) is used to throttle the vacuum pumping system 550. Desirably, plasma is utilized to create layers specific to a pre-determined layers process, and to aid either the deposition of layer to a substrate 525 or the removal of layer from the exposed surfaces of the substrate 525.

Substrate 525 is transferred into and out of chamber 510 through a slot valve (not shown) and chamber feed-through (not shown) via robotic substrate transfer system where it is received by substrate lift pins (not shown) housed within substrate holder 520 and mechanically translated by devices housed therein. Once the substrate 525 is received from the substrate transfer system, it is lowered to an upper surface of the substrate holder 520.

In an alternate embodiment, the substrate 525 is affixed to the substrate holder 520 via an electrostatic clamp (not shown). Furthermore, the substrate holder 520 further includes a cooling system including a re-circulating coolant flow that receives heat from the substrate holder 520 and transfers heat to a heat exchanger system (not shown), or when heating, transfers heat from the heat exchanger system. Moreover, gas may be delivered to the back-side of the substrate to improve the gas-gap thermal conductance between the substrate 525 and the substrate holder 520. Such a system is utilized when temperature control of the substrate is required at elevated or reduced temperatures. For example, temperature control of the substrate may be useful at temperatures in excess of the steady-state temperature achieved due to a balance of the heat flux delivered to the substrate 525 from the plasma and the heat flux removed from substrate 525 by conduction to the substrate holder 520. In other embodiments, heating elements, such as resistive heating elements, or thermo-electric heaters/coolers are included.

In a first embodiment, the substrate holder 520 further serves as an electrode through which radio frequency (RF) power is coupled to plasma in the processing region 545. For example, the substrate holder 520 is electrically biased at a RF voltage via the transmission of RF power from an RF generator 530 through an impedance match network 532 to the substrate holder 520. The RF bias serves to heat electrons and, thereby, form and maintain plasma. In this configuration, the system operates as a reactive ion etch (RIE) reactor, wherein the chamber and upper gas injection electrode serve as ground surfaces. A typical frequency for the RF bias ranges from 0.1 MHz to 100 MHz and may be 13.56 MHz. In an alternate embodiment, RF power is applied to the substrate holder electrode at multiple frequencies. Furthermore, the impedance match network 532 serves to maximize the transfer of RF power to plasma in process chamber 10 by minimizing the reflected power. Match network topologies (e.g. L-type, π-type, T-type, etc.) and automatic control methods are known in the art.

With continuing reference to FIG. 13, a process gas 542 (e.g., containing N₂, NH₃, H₂, NF₃ and optionally Ar) is introduced to the processing region 545 through the gas injection system 540. Gas injection system 540 can include a showerhead, wherein the process gas 542 is supplied from a gas delivery system (not shown) to the processing region 545 through a gas injection plenum (not shown), a series of baffle plates (not shown) and a multi-orifice showerhead gas injection plate (not shown).

Vacuum pumping system 550 preferably includes a turbo-molecular vacuum pump (TMP) capable of a pumping speed up to 5000 liters per second (and greater) and a gate valve for throttling the chamber pressure. In conventional plasma processing devices utilized for dry plasma etch, a 1000 to 3000 liter per second TMP is employed. TMPs are useful for low pressure processing, typically less than 50 mTorr. At higher pressures, the TMP pumping speed falls off dramatically. For high pressure processing (i.e. greater than 100 mTorr), a mechanical booster pump and dry roughing pump are used.

A computer 555 includes a microprocessor, a memory, and a digital I/O port capable of generating control voltages sufficient to communicate and activate inputs to the plasma processing system 500 as well as monitor outputs from the plasma processing system 500. Moreover, the computer 555 is coupled to and exchanges information with the RF generator 530, the impedance match network 532, the gas injection system 540 and the vacuum pumping system 550. A program stored in the memory is utilized to activate the inputs to the aforementioned components of a plasma processing system 500 according to a stored process recipe.

The plasma processing system 500 further includes an upper plate electrode 570 to which RF power is coupled from an RF generator 572 through an impedance match network 574. A typical frequency for the application of RF power to the upper electrode ranges from 10 MHz to 200 MHz and is preferably 60 MHz. Additionally, a typical frequency for the application of power to the lower electrode ranges from 0.1 MHz to 30 MHz. Moreover, the computer 555 is coupled to the RF generator 572 and the impedance match network 574 in order to control the application of RF power to the upper plate electrode 570.

Substrate processing methods using non-polymerizing chemistry to selectively etch SiO₂ relative to other layers has been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A substrate processing method, comprising:
providing a substrate containing a first layer containing SiO₂ and a second layer that is different from the first layer;
forming a plasma-excited process gas containing 1) NF₃ and NH₃, 2) NF₃, N₂ and H₂, or 3) NF₃, NH₃, N₂ and H₂; and
exposing the substrate to the plasma-excited process gas to selectively etch the first layer relative to the second layer.

2. The method of claim 1, wherein the second layer includes a Si-containing layer.

3. The method of claim 2, wherein the second layer includes SiN or elemental Si.

4. The method of claim 1, wherein the process gas consists of N₂, H₂, NH₃, and NF₃.

5. The method of claim 1, wherein the second layer includes raised features on the substrate and the first layer forms a conformal film on horizontal and vertical portions of the raised features, and wherein the exposing includes a spacer etch process that forms sidewall spacers of the first layer on the vertical portions of the raised features.

6. The method of claim 1, wherein the second layer includes raised features on the substrate, the first layer forms sidewall spacers on vertical portions of the raised features, and the exposing removes the sidewall spacers of the first layer from the raised features.

7. The method of claim 1, wherein the first layer includes raised features on the substrate, the second layer forms sidewall spacers on the vertical portions of the raised features, and wherein the exposing removes the raised features of the first layer but not the sidewall spacers.

8. The method of claim 1, wherein forming the plasma-excited process gas includes generating a plasma using a capacitively coupled plasma source containing an upper plate electrode and a lower plate electrode supporting the substrate.

9. The method of claim 1, wherein forming the plasma-excited process gas includes generating a plasma using a remote plasma source that creates a high radical to ion flux ratio.

10. The method of claim 1, wherein the exposing modifies the first layer to form a modified first layer on the first layer, the method further including removing the modified first layer by heating, ion bombardment, or both heating and ion bombardment.

11. The method of claim 1, wherein the second layer includes raised features on the substrate and the first layer forms a conformal film on horizontal and vertical portions of the raised features, the exposing modifying the first layer to form a modified first layer, the method further including removing the modified first layer from the horizontal portions of the raised features by ion bombardment to form sidewall spacers of the first layer on the vertical portions.

12. A substrate processing method, comprising:
providing a substrate containing a first layer containing SiO₂ and a second layer selected from the group consisting of elemental Si and SiN;
forming a plasma-excited process gas consisting of N₂, H₂, NH₃, and NF₃; and
exposing the substrate to the plasma-excited process gas to selectively etch the first layer relative to the second layer.

13. The method of claim 12, wherein the second layer includes raised features on the substrate and the first layer forms a conformal film on horizontal and vertical portions of the raised features, and wherein the exposing includes a spacer etch process that forms sidewall spacers of the first layer on the vertical portions of the raised features.

14. The method of claim 12, wherein the second layer includes raised features on the substrate, the first layer forms sidewall spacers on vertical portions of the raised features, and the exposing removes the sidewall spacers of the first layer from the raised features.

15. The method of claim 12, wherein the first layer includes raised features on the substrate, the second layer forms sidewall spacers on the vertical portions of the raised features, and wherein the exposing removes the raised features for the first layer but not the sidewall spacers.

16. The method of claim 12, wherein forming the plasma-excited process gas includes generating a plasma using a capacitively coupled plasma source containing an upper plate electrode and a lower plate electrode supporting the substrate.

17. The method of claim 12, wherein forming the plasma-excited process gas includes generating a plasma using a remote plasma source that creates a high radical to ion flux ratio.

18. The method of claim 12, wherein the exposing forms a modified first layer on the first layer, the method further including removing the modified first layer by heating, ion bombardment, or both heating and ion bombardment.

19. The method of claim 12, wherein the second layer includes raised features on the substrate and the first layer forms a conformal film on horizontal and vertical portions of the raised features, the exposing modifying the first layer to form a modified first layer, the method further including removing the modified first layer from the horizontal portions of the raised features by ion bombardment to form sidewall spacers of the first layer on the vertical portions.
